(19) United States
(12) Patent Application Publication
(10) Pub. No.: US 2021/0050407 A1
(43) Pub. Date: Feb. 18, 2021

(54) DISPLAY PANEL

(71) Applicant: Shenzhen China Star Optoelectronics Semiconductor Display Technology Co., Ltd., Shenzhen, Guangdong (CN)

(72) Inventor: Zhenfei CAI, Shenzhen, Guangdong (CN)

(21) Appl. No.: 16/620,893

(22) PCT Filed: Nov. 11, 2019
(86) PCT No.: PCT/CN2019/117147

§ 371 Date: Dec. 10, 2019

(30) Foreign Application Priority Data
Aug. 13, 2019 (CN) 201910742116.5

(51) Int. Cl. H01L 27/32

(52) U.S. Cl. CPC H01L 27/3279

(57) ABSTRACT

A display panel is provided, including a substrate, a first insulating layer, a plurality of gate lines, a second insulating layer, a plurality of data lines, a third insulating layer, a luminous layer, and a power cable. The substrate is provided with a plurality of thin film transistors. The first insulating layer covers the thin film transistors of the substrate. The plurality of gate lines are disposed on the first insulating layer, and the second insulating layer covers the gate lines. The plurality of data lines are disposed on the second insulating layer. The third insulating layer covers the data lines. The luminous layer includes a plurality of pixels. The power cable surrounds the luminous layer.

### FIELD OF DISCLOSURE

The present disclosure relates to the field of electronic displays, and in particular to a display panel.

### BACKGROUND

An active-matrix organic light-emitting diode (AMOLED) has a high contrast ratio, wide viewing angles, and fast response times. It is expected to replace a liquid crystal display as a mainstream for a next-generation display. FIG. 1 shows a power cable layout of an AMOLED display panel in the prior art. A power cable 30 is in connection through a chip on film (COF) around a source/drain metal layer. In order to reduce a voltage drop, the power cable 30 and data lines 10 around edges of the display area are connected together, i.e., the power cable 30 will cross all the data lines 10 in the panel.

Referring to FIG. 2, an interlayer dielectric layer 204 is disposed between the data lines 10 and gate lines 20. When a poor circuit or electrostatic breakdown occurs in the display panel, the power cable 30 is easily short-circuited with the gate line, causing the panel to burn out. Also, in the display panel using this layout, the power cable 30 is limited by a space of thin film transistors, and a line width cannot be made large, resulting in a relatively high resistance of the power cable 30, which increases a power loss of the display panel.

### SUMMARY OF DISCLOSURE

The present disclosure provides a display panel to solve the technical problem that a power cable is easy short-circuited with a gate line, resulting in a panel to be damaged.

To solve the above problem, the present disclosure provides a display panel, and the display panel includes a substrate, a first insulating layer, a plurality of gate lines, a second insulating layer, a plurality of data lines, a third insulating layer, a luminous layer, and a power cable.

The substrate is provided with a plurality of thin film transistors.

The first insulating layer covers the thin film transistors of the substrate.

The plurality of gate lines are disposed on the first insulating layer and connected to gates of the plurality of thin film transistors by a plurality of first through holes.

The second insulating layer covers the gate lines.

The plurality of data lines are disposed on the second insulating layer and connected to sources and drains of the plurality of thin film transistors by a plurality of second through holes.

The third insulating layer covers the data lines.

The luminous layer includes a plurality of pixels, and cathodes of the pixels include a conductive film.

The power cable surrounds the conductive film and is electrically connected to the data lines by a plurality of third through holes.

According to one aspect of the present disclosure, each of the pixels comprises an anode, a pixel definition layer, a luminescent material, and one of the cathodes.

The anode is disposed on the third insulating layer.

The pixel definition layer is disposed on the third insulating layer and includes an opening that exposes the anode.

The luminescent material is disposed in the opening and electrically connected to the anode.

The cathode coves the pixel definition layer and the conductive film of the luminescent material.

According to one aspect of the present disclosure, the plurality of the gate lines are a plurality of conductive metals arranged in parallel, and the plurality of gate lines extend in a first direction.

According to one aspect of the present disclosure, the plurality of gate lines are arranged apart from each other, and distances between any two adjacent gate lines are equal.

According to one aspect of the present disclosure, the plurality of data lines are a plurality of conductive metals arranged in parallel, the plurality of data lines extend in a second direction, and the second direction is perpendicular to the first direction.

According to one aspect of the present disclosure, the plurality of data lines are arranged apart from each other, and distances between any two adjacent data lines are equal.

According to one aspect of the present disclosure, each of the data lines includes a first end and a second end, and a data signal is input into the first end of each of the data lines, and the second end of each of the data lines is powered through a first connection line extending in the first direction.

According to one aspect of the present disclosure, the first connection line is located directly under the power cable, and two third through holes are respectively disposed at two ends of the first connection line such that the first connection line is electrically connected to the power cable.

According to one aspect of the present disclosure, the plurality data lines include at least two second connection lines, the second connection lines are disposed on both sides of the first end of one of the data lines, an input signal is input into one end of one of the second connection lines, and another end of one of the second connection lines is disposed directly below the power cable and is electrically connected to the power cable through a third through hole.

According to one aspect of the present disclosure, a width of the power cable is greater than or equal to twice a width of one of the data lines.

In comparation to the display panel in which the power cable and the data lines are disposed on the same layer in the prior art, the display panel of the present disclosure sets the power cable and the cathodes on the same layer. The metal film surrounding the cathodes is used as the power cable. The electrical connection between the power cable and the data lines is realized through the through hole. After arranging those in different layers, the power cable and the gate lines are separated by at least three insulating layers, which greatly reduces a probability of a short circuit between the power cable and the gate lines. Since the power cable and the data lines are arranged in different layers, the power cable is not limited by a layout of the data lines, and a line width can be several times a line width of the data line, thereby effectively reducing an impedance of the power cable and avoiding uneven brightness caused by a voltage drop.

### BRIEF DESCRIPTION OF DRAWINGS

FIG. 1 is a schematic diagram of metal lines of a display panel in the prior art.

FIG. 2 is a schematic diagram of the display panel in the prior art.

FIG. 3 is a schematic diagram of metal lines of a display panel of a specific embodiment of the present disclosure.

FIG. 4 is a schematic diagram of the display panel of the specific embodiment of the present disclosure.

### DETAILED DESCRIPTION

The structure and the technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, and etc., are only directions by referring to the accompanying drawings. Therefore, the used directional terms are used to describe and understand the present disclosure, but the present disclosure is not limited thereto. In the figures, the similar structural units are designated by the same reference numbers.

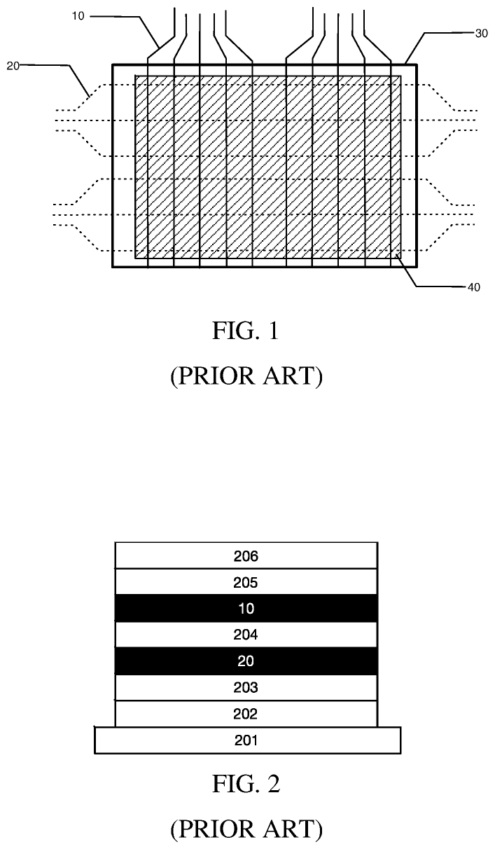

First, the prior art will be briefly described. Referring to FIG. 1 and FIG. 2, FIG. 1 is a schematic diagram of metal lines of a display panel in the prior art, and FIG. 2 is a schematic diagram of the display panel in the prior art.

In the prior art, a power cable 30 is in connection through a COF around a source/drain metal layer. In order to reduce a voltage drop, the power cable 30 and data lines 10 around edges of the display area are connected together, i.e., the power cable 30 will cross all the data lines 10 in the panel.

Referring to FIG. 2, a stacked structure of the display panel of the prior art generally includes a base 201, a buffer layer 202, a thin film transistor layer 203, an interlayer dielectric layer 204, a planarization layer 205, and a pixel definition layer 206. Gate lines are disposed between the thin film transistor layer 203 and the interlayer dielectric layer 204. The data lines 10 are disposed between the interface dielectric layer 204 and the planarization layer 205. There is only one interlayer dielectric layer 204 between the data lines 10 and the gate lines 20. Therefore, when a poor circuit or electrostatic breakdown occurs in the display panel, the power cable 30 is easily short-circuited with the gate lines 10, causing the panel to burn out. Also, in the display panel using this layout, the power cable 30 is limited by the layout of the data lines 10, and a line width cannot be made large, resulting in a relatively high resistance of the power cable 30, which increases a power loss of the display panel.

Therefore, the present disclosure provides a display panel to solve the technical problem that the power cable is easily short-circuited with the gate lines to cause panel damage.

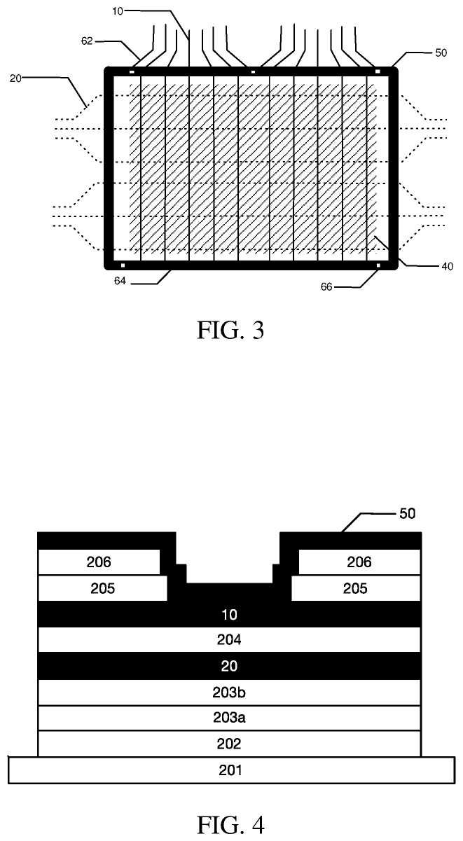

One of the embodiments of the present disclosure will be described in detail below with reference to the accompanying drawings. Referring to FIG. 3 and FIG. 4, FIG. 3 is a schematic diagram of metal lines of a display panel of a specific embodiment of the present disclosure, and FIG. 4 is a schematic diagram of the display panel of the specific embodiment of the present disclosure.

In the embodiment, the display panel includes a substrate, a first insulating layer, a plurality of gate lines 20, a second insulating layer, a plurality of data lines 10, a third insulating layer, a luminous layer, a power cable 50.

The substrate is provided with a plurality of thin film transistors. Specifically, the substrate includes a base 201, a buffer layer 202 disposed on the base, and a thin film transistor layer 203a disposed on the buffer layer 202. The thin film transistor layer 203a includes an active region and a gate stacked layer over the active region. The active region includes a channel region and a source region, a drain region. The gate stacked layer is disposed over the channel region and includes a gate dielectric layer and a gate metal layer disposed over the gate dielectric layer.

The first insulating layer 203b covers the thin film transistors of the substrate, that is, the first insulating layer 203b covers the active region and the gate stacked layer.

The plurality of gate lines 20 are disposed on the first insulating layer 203b. Gate signals are input into one ends of the plurality of gate lines 20. The other ends of the plurality of gate lines 20 are electrically connected to the gate stacked layer of the plurality of thin film transistors by a plurality of first through holes.

The plurality of gate lines 20 are configured to provide gate control signals to the gates of the plurality thin film transistors of the substrate. In this embodiment, the plurality of gate lines 20 are a plurality of conductive metals arranged in parallel, and the plurality of gate lines 20 extend in a first direction. The first direction is parallel to one side of the display panel. The plurality of gate lines 20 are arranged apart from each other, and distances between any two adjacent gate lines are equal.

The second insulating layer 204 covers the gate lines 20. In this embodiment, the second insulating layer 204 is an interlayer dielectric layer.

The plurality of data lines 10 are disposed on the second insulating layer 204. Signal are input into one ends of the plurality of data lines 10. The other ends of the plurality of data lines 10 are electrically connected to the source and drain regions of the plurality of thin film transistors by a plurality of second through holes.

The third insulating layer covers the data lines. In this embodiment, the third insulating layer is a planarization layer 205.

The luminous layer includes a plurality of pixels, and each of the pixels includes an anode, a pixel definition layer 206, a luminescent material, and a cathode 40. Since the schematic diagram shown in FIG. 4 is a cross-sectional view of a wiring area in which the power cable 50 is located, the anode, the luminescent material, and the cathode are not shown in FIG. 4. The anode is disposed on the third insulating layer 205. The pixel definition layer 206 is disposed on the third insulating layer 205 and includes an opening that exposes the anode. The luminescent material is disposed in the opening and is electrically connected to the anode. Referring to FIG. 3, the cathodes 40 are a conductive film covering the pixel definition layer and the luminescent material.

The power cable 50 surrounds the conductive film and is electrically connected to the data lines 10 through a plurality of third through holes 66.

The data line is configured used to provide a driving voltage to a source or drain region of one of the thin film transistors of the substrate. In this embodiment, the plurality of data lines 10 are a plurality of conductive metals arranged in parallel, and the plurality of data lines 10 extend in a second direction. The second direction is perpendicular to the first direction. The plurality of data lines 10 are arranged apart from each other, and distances between any two adjacent data lines 10 are equal.

In this embodiment, each of the data lines includes a first end and a second end. A data signal is input into the first end of one of the data lines. The second end of one of the data lines is powered by a first connection line 64 extending in the first direction. The first connection line 64 is disposed directly below the power cable 50. Two third through holes 66 are respectively disposed at two ends of the first connection line 64 such that the first connection line 64 is electrically connected to the power cable 50 to supply a power voltage for the plurality of data lines.

In order to avoid a voltage drop, the plurality of data lines 10 also includes at least two second connection lines 62. The second connection lines 62 are disposed on both sides of the first end of one of the data lines 10. A signal is input into one end of one of the second connection lines 62. The other end of one of the second connection lines 62 is disposed directly below the power cable 50 and is electrically connected to the power cable 50 through a third through hole 66. The greater the number of third through holes 66 provided, the smaller the voltage drop across the power cable 50. In practical applications, the number of the third through holes 66 can be set as needed. Preferably, the number of the third through holes 66 is equal to the number of the data lines 10.

In this embodiment, since the power cable 50 and the data lines 10 are arranged in different layers, the power cable 50 can be not limited by the layout of the data lines 10, and a line width can be several times a line width of one of the data lines, thereby effectively reducing an impedance of the power cable and avoiding uneven brightness caused by a voltage drop. Preferably, the width of the power cable 50 is greater than or equal to twice a width of the data line 10.

In comparation to the display panel in which the power cable and the data lines are disposed on the same layer in the prior art, the display panel of the present disclosure sets the power cable and the cathodes on the same layer. The metal film surrounding the cathodes is used as the power cable. The electrical connection between the power cable and the data lines is realized through the through hole. After arranging those in different layers, the power cable and the gate lines are separated by at least three insulating layers, which greatly reduces a probability of a short circuit between the power cable and the gate lines. Since the power cable and the data lines are arranged in different layers, the power cable is not limited by a layout of the data lines, and a line width can be several times a line width of the data line, thereby effectively reducing an impedance of the power cable and avoiding uneven brightness caused by a voltage drop.

In the above, although the present disclosure has been disclosed above in the preferred embodiments, the preferred embodiments are not intended to limit the present disclosure. Various modifications and replacements can be made by those skilled in the art without departing from the spirit and scope of the present disclosure. Accordingly, the scope of protection of the present disclosure is subject to the scope defined by the claims.

What is claimed is:

1. A display panel, comprising:
a substrate provided with a plurality of thin film transistors;
a first insulating layer covering the thin film transistors of the substrate;
a plurality of gate lines disposed on the first insulating layer and connected to gates of the plurality of thin film transistors by a plurality of first through holes;
a second insulating layer covering the gate lines;
a plurality of data lines disposed on the second insulating layer and connected to sources and drains of the plurality of thin film transistors by a plurality of second through holes;
a third insulating layer covering the data lines;
a luminous layer comprising a plurality of pixels, wherein cathodes of the pixels comprise a conductive film; and
a power cable surrounding the conductive film and electrically connected to the data lines by a plurality of third through holes.

2. The display panel as claimed in claim 1, wherein each of the pixels comprises:
an anode disposed on the third insulating layer;
a pixel definition layer disposed on the third insulating layer and comprising an opening that exposes the anode;
a luminescent material disposed in the opening and electrically connected to the anode; and
one of the cathodes covering the pixel definition layer and the conductive film of the luminescent material.

3. The display panel as claimed in claim 1, wherein the plurality of the gate lines are a plurality of conductive metals arranged in parallel, and the plurality of gate lines extend in a first direction.

4. The display panel as claimed in claim 3, wherein the plurality of gate lines are arranged apart from each other, and distances between any two adjacent gate lines are equal.

5. The display panel as claimed in claim 3, wherein the plurality of data lines are a plurality of conductive metals arranged in parallel, the plurality of data lines extend in a second direction, and the second direction is perpendicular to the first direction.

6. The display panel as claimed in claim 5, wherein the plurality of data lines are arranged apart from each other, and distances between any two adjacent data lines are equal.

7. The display panel as claimed in claim 5, wherein each of the data lines comprises a first end and a second end, and a data signal is input into the first end of each of the data lines, and the second end of each of the data lines is powered through a first connection line extending in the first direction.

8. The display panel as claimed in claim 7, wherein the first connection line is located directly under the power cable, and two third through holes are respectively disposed at two ends of the first connection line such that the first connection line is electrically connected to the power cable.

9. The display panel as claimed in claim 7, wherein the plurality data lines comprise at least two second connection lines, the second connection lines are disposed on both sides of the first end of one of the data lines, an input signal is input into one end of one of the second connection lines, and another end of one of the second connection lines is disposed directly below the power cable and is electrically connected to the power cable through a third through hole.

10. The display panel as claimed in claim 1, wherein a width of the power cable is greater than or equal to twice a width of one of the data lines.
